(19) United States
(12) Patent Application Publication
(10) Pub. No.: US 2025/0241120 A1
(43) Pub. Date: Jul. 24, 2025

(54) ORGANIC ELECTROLUMINESCENT DEVICE AND DISPLAY EQUIPMENT

(71) Applicants: HEFEI BOE JOINT TECHNOLOGY CO., LTD., Hefei, Anhui (CN); BOE TECHNOLOGY GROUP CO., LTD., Beijing (CN)

(72) Inventors: Xinxin WANG, Beijing (CN); Xiang WAN, Beijing (CN); Xinyu LI, Beijing (CN); Cheng XU, Beijing (CN); Dandan ZHOU, Beijing (CN); Ningning WANG, Beijing (CN)

(73) Assignees: HEFEI BOE JOINT TECHNOLOGY CO., LTD., Hefei, Anhui (CN); BOE TECHNOLOGY GROUP CO., LTD., Beijing (CN)

(21) Appl. No.: 18/699,610

(22) PCT Filed: Mar. 28, 2023
(86) PCT No.: PCT/CN2023/084499

§ 371 Date: Apr. 9, 2024

(51) Int. Cl. H10K 50/16; H10K 50/165; H10K 101/30; H10K 102/00

(52) U.S. Cl. CPC H10K 50/166; H10K 50/165; H10K 2101/30; H10K 2102/351

(57) ABSTRACT

At least one embodiment of the present disclosure provides an organic electroluminescent device, which includes: a base substrate, and a light-emitting layer, an electron transport layer, and a first electrode layer sequentially stacked on the base substrate, the electron transport layer includes a multilayer structure that is stacked, and a material of at least one layer in the multilayer structure includes lithium metal, the electron transport layer with a thicker thickness is divided into a structure with at least two layers that are stacked, and at least one layer of the multilayer structure contains the lithium metal, which can minimize the impact of the magnetron sputtering process used to form the cathode layer on the electron injection capability of the organic electroluminescent devices to the greatest extent.

### TECHNICAL FIELD

Embodiments of the present disclosure relate to an organic electroluminescent device and a display equipment.

### BACKGROUND

Organic electroluminescent (OLED) devices are known as the new generation of flat panel display devices, have advantages such as self-illumination, wide viewing angle, high contrast, fast reaction time, and flexible display, and have the potential to become the mainstream display devices of the next generation and are currently one of the most concerned technologies of the display devices. Organic electroluminescent devices are current type organic electroluminescent devices, the light-emitting principle is to emit light through the injection and recombination of charge carriers. The light-emitting intensity of the organic electroluminescent device is directly proportional to the amount of injected electrons and holes. The organic electroluminescent device typically includes a cathode layer, an anode layer, and includes an electron transport layer, a hole transport layer, and an organic light-emitting material layer that are between the cathode layer and the anode layer. Under the influence of an external voltage, holes injected from the anode layer and electrons injected from the cathode layer are respectively transmitted to the organic light-emitting material layer. When the electrons and the holes meet in the organic light-emitting material layer, energy excitons are generated, which will excite light-emitting molecules to ultimately generate visible light.

According to different emitting surfaces, organic electroluminescent display devices can be divided into two types: bottom emitting OLED display devices and top emitting OLED display devices. Because of the fact that the top emitting OLED display devices can achieve a larger opening rate, the top emitting OLED display devices have become a research hotspot in recent years. The top emitting OLED display devices require a thin and transparent cathode layer and an anode layer that can reflect light to increase light transmittance.

### SUMMARY

Embodiments of the present disclosure relate to an organic electroluminescent device and a display equipment, the electron transport layer of the organic electroluminescent device comprises a multilayer structure that is stacked, and a material of at least one layer in the multilayer structure comprises lithium metal, that is the electron transport layer with a thicker thickness is divided into a structure with at least two layers that are stacked, and at least one layer contains lithium metal, which can minimize the impact of the magnetron sputtering process used to form the cathode layer on the electron injection capability of the organic electroluminescent devices to the greatest extent, and at the same time, the efficiency of the organic electroluminescent devices can be improved by at least 7% to 10%.

At least one embodiment of the present disclosure provides an organic electroluminescent device, and the organic electroluminescent device includes: a base substrate, and a light-emitting layer, an electron transport layer, and a first electrode layer sequentially stacked on the base substrate, in which the electron transport layer comprises a multilayer structure that is stacked, and a material of at least one layer in the multilayer structure comprises lithium metal.

For example, in the organic electroluminescent device provided by at least one embodiment of the present disclosure, the electron transport layer comprises a first electron transport sub-layer and a second electron transport sub-layer that are stacked, the first electron transport sub-layer is sandwiched between the light-emitting layer and the second electron transport sub-layer, and a material of the first electron transport sub-layer comprises a first electron transport material, and a material of the second electron transport sub-layer comprises the lithium metal.

For example, in the organic electroluminescent device provided by at least one embodiment of the present disclosure, the material of the second electron transport sub-layer further comprises a second electron transport material, the lithium metal is doped in the second electron transport material, and in a direction perpendicular to a main surface of the base substrate, a thickness of the first electron transport sub-layer is greater than a thickness of the second electron transport sub-layer.

For example, in the organic electroluminescent device provided by at least one embodiment of the present disclosure, the thickness of the first electron transport sub-layer is 2 to 6 times the thickness of the second electron transport sub-layer.

For example, in the organic electroluminescent device provided by at least one embodiment of the present disclosure, the thickness of the first electron transport sub-layer ranges from 600 angstroms to 1000 angstroms, the thickness of the second electron transport sub-layer ranges from 150 angstroms to 250 angstroms, a thickness of the first electrode layer ranges from 600 angstroms to 1000 angstroms, and in the second electron transport sub-layer, a mass doping ratio of the lithium metal ranges from 5% to 12%.

For example, in the organic electroluminescent device provided by at least one embodiment of the present disclosure, the thickness of the first electron transport sub-layer is 800 angstroms, the thickness of the second electron transport sub-layer is 200 angstroms, and in the second electron transport sub-layer, the mass doping ratio of the lithium metal is 10%.

For example, in the organic electroluminescent device provided by at least one embodiment of the present disclosure, the thickness of the first electron transport sub-layer is 3 to 15 times the thickness of the second electron transport sub-layer.

For example, in the organic electroluminescent device provided by at least one embodiment of the present disclosure, the thickness of the first electron transport sub-layer ranges from 1000 angstroms to 1500 angstroms, the thickness of the second electron transport sub-layer ranges from 100 angstroms to 300 angstroms, and a thickness of the first electrode layer ranges from 400 angstroms to 600 angstroms.

For example, in the organic electroluminescent device provided by at least one embodiment of the present disclosure, the thickness of the first electron transport sub-layer is 1250 angstroms, the thickness of the second electron transport sub-layer is 200 angstroms, and the thickness of the first electrode layer is 300 angstroms.

For example, in the organic electroluminescent device provided by at least one embodiment of the present disclosure, lowest unoccupied molecular orbital energy levels of the first electron transport sub-layer and the second electron transport sub-layer both range from −2.75 eV to −2.9 eV, highest occupied molecular orbital energy levels of the first electron transport sub-layer and the second electron transport sub-layer both range from −6.0 eV to −6.2 eV, and electron mobilities of the first electron transport sub-layer and the second electron transport sub-layer both range from 10⁻³ cm²/(V*s) to 10⁻² cm²/(V*s).

For example, in the organic electroluminescent device provided by at least one embodiment of the present disclosure, the second electron transport sub-layer is formed of an alloy material of the lithium metal and yttrium metal.

For example, in the organic electroluminescent device provided by at least one embodiment of the present disclosure, an electron mobility of the first electron transport material ranges from 10⁻² cm²/(V*s) to 10⁻¹ cm²(V*s).

For example, in the organic electroluminescent device provided by at least one embodiment of the present disclosure, in a direction perpendicular to a main surface of the base substrate, the thickness of the second electron transport sub-layer ranges from 5 nm to 15 nm, and the thickness of the first electron transport sub-layer ranges from 70 nm to 90 nm.

For example, in the organic electroluminescent device provided by at least one embodiment of the present disclosure, the second electron transport sub-layer comprises a first portion and a second portion that are stacked, a material of the first portion comprises a second electron transport material, and the lithium metal is doped in the second electron transport material; the second portion is formed of an alloy material of the lithium metal and yttrium metal, and in a direction perpendicular to a main surface of the base substrate, the thickness of the first electron transport sub-layer is smaller the thickness of the second electron transport sub-layer.

For example, in the organic electroluminescent device provided by at least one embodiment of the present disclosure, electron mobilities of the first electron transport material and the second electron transport material both range from 10⁻³ cm²/(V*s) to 10⁻² cm²/(V*s).

For example, in the organic electroluminescent device provided by at least one embodiment of the present disclosure, in the direction perpendicular to the main surface of the base substrate, the thickness of the second portion ranges from 5 nm to 15 nm, and a sum of thicknesses of the first electron transport sub-layer and the first portion ranges from 70 nm to 90 nm.

For example, in the organic electroluminescent device provided by at least one embodiment of the present disclosure, the electron transport layer comprises a first electron transport sub-layer and a second electron transport sub-layer that are stacked, the first electron transport sub-layer is sandwiched between the light-emitting layer and the second electron transport sub-layer, and a material of the first electron transport sub-layer comprises a third electron transport material and the lithium metal doped in the third electron transport material, the second electron transport sub-layer is formed of an alloy material of magnesium metal and silver metal.

For example, in the organic eleetroluminescent device provided by at least one embodiment of the present disclosure, in the second electron transport sub-layer, a mass ratio of the magnesium metal to the silver metal ranges from 9:1 to 8:2.

For example, in the organic eleetroluminescent device provided by at least one embodiment of the present disclosure, in the direction perpendicular to the main surface of the base substrate, a thickness of the second electron transport sub-layer ranges from 2 nm to 5 nm, and a thickness of the first electron transport sub-layer ranges from 73 nm to 100 nm.

For example, in the organic electroluminescent device provided by at least one embodiment of the present disclosure, in the direction perpendicular to the main surface of the base substrate, a thickness of the second electron transport sub-layer ranges from 2 nm to 5 nm, and a thickness of the first electron transport sub-layer ranges from 100 nm to 120 nm.

For example, in the organic electroluminescent device provided by at least one embodiment of the present disclosure, a material of the first electrode layer comprises indium zinc oxide.

For example, in the organic electroluminescent device provided by at least one embodiment of the present disclosure, the light-emitting layer comprises a blue light-emitting layer, a red light-emitting layer, and a green light-emitting layer, in a direction perpendicular to a main surface of the base substrate, a thickness of the blue light-emitting layer ranges from 200 angstroms to 300 angstroms, a thickness of the red light-emitting layer ranges from 100 angstroms to 200 angstroms, and a thickness of the green light-emitting layer ranges from 400 angstroms to 500 angstroms.

For example, the organic electroluminescent device provided by at least one embodiment of the present disclosure, further comprises: a second electrode layer on a side of the light-emitting layer away from the first electrode layer, and a material of the second electrode layer comprises at least one of aluminum, silver, molybdenum, and copper.

At least one embodiment of the present disclosure further provides a display equipment, and the display equipment includes any one of the organic electroluminescent devices mentioned above.

### BRIEF DESCRIPTION OF DRAWINGS

In order to clearly illustrate technical solutions of the embodiments of the present disclosure, the drawings of the embodiments will be briefly described. It is obvious that the described drawings in the following are only related to some embodiments of the present disclosure and thus are not construed as any limitation to the present disclosure.

FIG. 1 is a schematic cross-sectional diagram of an organic electroluminescent device provided by at least one embodiment of the present disclosure;

FIG. 2 is a schematic cross-sectional diagram of another organic electroluminescent device provided by at least one embodiment of the present disclosure;

FIG. 3 is a schematic cross-sectional diagram of further another organic electroluminescent device provided by at least one embodiment of the present disclosure;

FIG. 4 is a schematic cross-sectional diagram of further another organic electroluminescent device provided by at least one embodiment of the present disclosure;

FIG. 5 is a schematic cross-sectional diagram of further another organic electroluminescent device provided by at least one embodiment of the present disclosure;

FIG. 6 is a schematic cross-sectional diagram of further another organic electroluminescent device provided by at least one embodiment of the present disclosure;

FIG. 7 is a schematic cross-sectional diagram of further another organic electroluminescent device provided by at least one embodiment of the present disclosure;

FIG. 8 is a schematic cross-sectional diagram of further another organic electroluminescent device provided by at least one embodiment of the present disclosure;

FIG. 9 is a schematic cross-sectional diagram of further another organic electroluminescent device provided by at least one embodiment of the present disclosure; and

FIG. 10 is a block diagram of a display equipment provided by at least one embodiment of the present disclosure.

### DETAILED DESCRIPTION

In order to make objectives, technical details, and advantages of the embodiments of the present disclosure clearer, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first”, “second”, etc., which are used in the present disclosure, are not intended to indicate any sequence, amount or importance, but distinguish various components. Also, the terms “comprise,” “comprising,” “include.” “including.” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “left,” “right” and the like are only used to indicate relative position relationship, and when the position of the object which is described is changed, the relative position relationship may be changed accordingly.

Unless otherwise defined, the features such as “parallel”, “vertical”, and “identical” used in the embodiments of the present disclosure all include strictly defined cases such as “parallel”, “vertical”, “identical”, as well as cases where “roughly parallel”, “roughly vertical”, “roughly identical”, and so on contain certain errors. For example, the above “roughly” can indicate that the difference between the compared objects is 10% of the average value of the compared objects, or within 5%. When the quantity of a component or an element is not specifically specified in the following text of the embodiments of the present disclosure, it means that the component or the element can be one or multiple, or can be understood as at least one. “At least one” refers to one or more, and “multiple” refers to at least two. The “same layer arranging” in the embodiments of the present disclosure refers to the relationship between multiple film layers formed by the same material after undergoing the same step (such as a one-step patterning process). The term “same layer” herein does not always refer to multiple film layers with the same thickness or multiple film layers with the same height in the cross-sectional view.

For large-sized top emitting organic electroluminescent devices, a semi-transparent cathode layer is usually used. The material of the cathode layer usually includes indium zinc oxide, and the cathode layer is usually formed by a magnetron sputtering method. However, when using the magnetron sputtering process to prepare the cathode layer, the process can cause certain damage to functional layers such as the light-emitting material layer. For example, the magnetron sputtering process requires particles to bombard a target material, which then the target material deposits on a base substrate to form a cathode film layer. When particles deposit onto the base substrate, the particles will have a certain amount of energy, which can cause certain damage to the light-emitting material layer, thereby affecting the number of electrons injected and transmitted to the light-emitting material layer, reducing the number of electrons transmitted to the light-emitting material layer, and ultimately shortening the lifetime of the formed organic electroluminescent device.

At present, the material of the electron transport layer adjacent to the cathode layer usually include a lithium doped electron transport material (ETL: Li). In order to achieve better electron injection and electron transport effects, the concentration of lithium metal in the electron transport layer is usually high, and the thickness of the electron transport layer (ETL: Li) is also usually large. However, the inventors of the present disclosure note that, for example, in the process of manufacturing a 55 inch top emitting organic electroluminescent device, the thickness and a mass concentration of the doped metal in the material of the electron transport layer adjacent to the cathode layer have a significant impact on the lifetime of the organic electroluminescent device, especially the concentration of the lithium metal in the electron transport layer can have a significant impact on the lifetime of the organic electroluminescent device. If the whole electron transport layer adjacent to the cathode layer is formed of a material with high lithium metal concentration, for example, when using an electron transport material doped with the lithium metal, in which a mass percentage content of the lithium metal is greater than 10%, to form the electron transport layer, although the lifetime of the organic electroluminescent device can be increased by 60%, the light-emitting efficiency of the organic electroluminescent device will be reduced by 10% to 15% due to the increased absorption of the lithium metal, as a result, the loss of the light-emitting efficiency is too high.

The inventors of the present disclosure also note that designing the electron transport layer with a thicker thickness as a multilayer structure that is stacked, for example, designing the electron transport layer with a thicker thickness as a multilayer structure in which a transition layer only including the electron transport material and an electron transport layer doped with the lithium metal are stacked, and designing the original single-layer electron transport layer doped with the lithium metal with a thickness of 800 angstroms to 1200 angstroms as a multilayer structure in which a transition layer and an electron transport layer doped with the lithium metal are stacked, the damage to the light-emitting material layer during the formation of the cathode layer using the magnetron sputtering method can be greatly reduced to ensure the electron injection capability, and the light-emitting efficiency of the organic electroluminescent device can also be improved by 7% to 10% on the original basis.

At least one embodiment of the present disclosure provides an organic electroluminescent device, the organic electroluminescent device includes a base substrate, and a light-emitting layer, an electron transport layer, and a first electrode layer sequentially stacked on the base substrate, the electron transport layer includes a multilayer structure that is stacked, and a material of at least one layer in the multilayer structure includes lithium metal. This design can minimize the impact of the magnetron sputtering process used to form the cathode layer on the electron injection capability of the organic electroluminescent device, and improve the efficiency of the organic electroluminescent device by at least 7% to 10%.

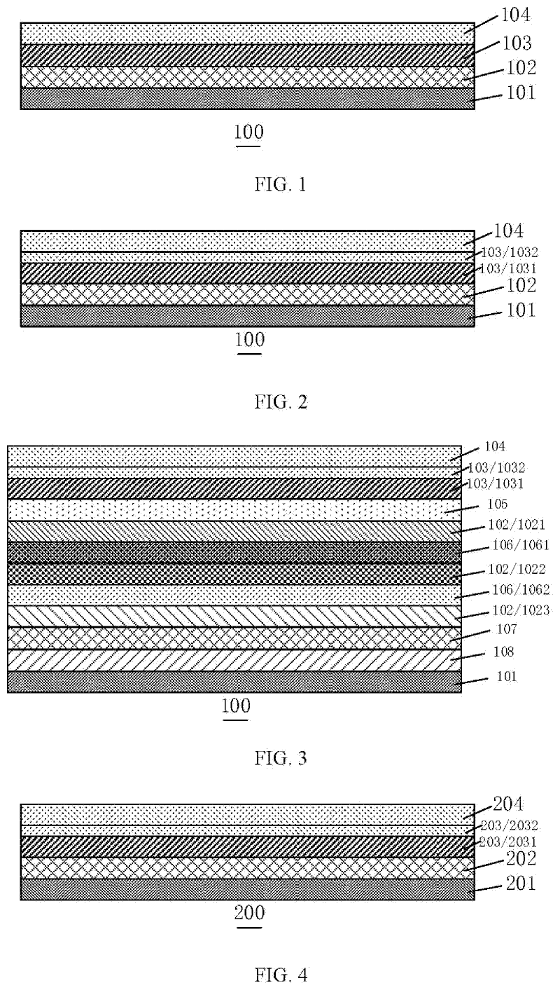

For example, FIG. 1 is a schematic cross-sectional diagram of an organic electroluminescent device provided by at least one embodiment of the present disclosure. As shown in FIG. 1, the organic electroluminescent device 100 includes a base substrate 101, and a light-emitting layer 102, an electron transport layer 103, and a first electrode layer 104 that are sequentially stacked on the base substrate 101. The electron transport layer 103 includes a multilayer structure that is stacked, although FIG. 1 does not clearly show that the electron transport layer 103 includes a multilayer structure that is stacked, and the material of at least one layer in the multilayer structure includes the lithium metal, that is, there is no clear design of the electron transport layer of the thicker single-layer doped the lithium metal as a multilayer structure that is stacked, and the material of at least one layer in the multilayer structure including the lithium metal, the schematic diagram of the organic electroluminescent device shown in FIG. 1 can greatly reduce the damage to the light-emitting layer during the formation of the first electrode layer by the magnetron sputtering method to ensure electron injection capability, and the light-emitting efficiency of the organic electroluminescent device can also be improved by 7% to 10%. For example, in one example, the light-emitting efficiency of the organic electroluminescent device can be improved by 8% to 9%. For example, in another example, the light-emitting efficiency of the organic electroluminescent device can be improved by 7%, 8%, 9%, or 10%, which is not limited by the embodiments of the present disclosure.

For example, a material of the first electrode layer 102 may include a transparent conductive material, for example, the transparent conductive material may be indium tin oxide (ITO) or indium zinc oxide (IZO), the embodiments of the present disclosure are not limited to this. The first electrode layer 102 is formed by the magnetron sputtering process, when the first electrode layer 102 is formed by the magnetron sputtering process, the process will cause certain damage to the organic electroluminescent device, which will affect the electron injection effect and thus affect the lifetime of the organic electroluminescent device. The electron transport layer 103 is set to include the multilayer structure that is stacked, and the layer structure far away from the light-emitting layer can protect the light-emitting layer.

For example, the base substrate 101 may be a flexible base substrate, for example, the flexible base substrate includes a first flexible material layer, a first inorganic material layer, a second flexible material layer, or a second inorganic material layer that are stacked on a glass carrier plate. The materials of the first flexible material layer and the second flexible material layer are polyimide (PI), polyethylene terephthalate (PET), surface treated polymer soft films, or the like. The materials of the first inorganic material layer and the second inorganic material layer are silicon nitride (SiNx), silicon oxide (SiOx), or the like to improve the water oxygen resistance ability of the base substrate. The first inorganic material layer and the second inorganic material layer are also known as barrier layers.

For example, designing the material of at least one layer in the multilayer structure that is stacked included in the electron transport layer 103 to include the lithium metal, and the material of at least another layer to not include the lithium metal, or in the material design of at least another layer, designing a mass concentration of the lithium metal in the electron transport material to be low, in the overall structure formed by the multilayer structure, this design can ensure that the mass percentage content of the lithium metal in the electron transport material doped with the lithium metal is around 10%, so that when the light-emitting efficiency of the organic electroluminescent device is improved, the lifetime of the organic eleetroluminescent device will not be shortened.

It should be noted that, although not shown in FIG. 1, the multilayer structure may be a sequentially stacked two-layer structure, three-layer structure, four-layer structure, or more-layer structure with more than four layers.

It should also be noted that other conventional structures of the organic electroluminescent device, such as a hole injection layer, a hole transport layer, an electron injection layer, and a second electrode layer, are omitted in FIG. 1. The materials and thicknesses of these omitted structures can refer to conventional designs, and the embodiments of the present disclosure are not limited to this.

For example, FIG. 2 is a schematic cross-sectional diagram of another organic electroluminescent device provided by at least one embodiment of the present disclosure, as shown in FIG. 2. The electron transport layer 103 includes a first electron transport sub-layer 1031 and a second electron transport sub-layer 1032 that are stacked. The first electron transport sub-layer 1031 is sandwiched between the light-emitting layer 102 and the second electron transport sub-layer 1032, and the first electron transport sub-layer 1031 includes a first electron transport material, and a material of the second electron transport sub-layer 1032 includes the lithium metal. FIG. 2 takes the electron transport layer 103 including a two-layer structure that is stacked as an example. Of course, the number of layers included in the electron transport layer 103 is not limited to this. The material of the second electron transport sub-layer 1032 may not only include the lithium metal, but also include an electron transport material, or may also include other metals to form an alloy of the lithium metal and other metals, the embodiments of the present disclosure are not limited to this.

For example, referring to FIG. 2, in one example, in the organic electroluminescent device 100, the material of the second electron transport sub-layer 1032 further includes a second electron transport material, the lithium metal is doped in the second electron transport material, and in a direction perpendicular to a main surface of the base substrate 101, the thickness of the first electron transport sub-layer 1031 is greater than the thickness of the second electron transport sub-layer 1032. The first electron transport material may be the same as or different from the second electron transport material, and the embodiments of the present disclosure are not limited to this. In the case where the first electron transport material and the second electron transport material are the same, the variety of electron transport materials can be reduced, so that changing a single variable can be better achieved while keeping the thickness unchanged, so as to better control the mass concentration of the doped lithium metal and simplify the operation process. In the case where the first electron transport material and the second electron transport material are different, and the first electron transport sub-layer 1031 is only formed by the first electron transport material, the conductivity of the first electron transport material is better than the conductivity of the second electron transport material. In the case where the first electron transport material and the second electron transport material are the same, and the first electron transport sub-layer 1031 includes the first electron transport material and the lithium metal doped in the first electron transport material, the mass percentage content of the lithium metal doped in the first electron transport material is smaller than the mass percentage content of the lithium metal doped in the second electron transport material. For example, the mass percentage content of the lithium metal doped in the first electron transport material ranges from 1% to 5%, and the mass percentage content of the lithium metal doped in the second electron transport material ranges from 5% to 12%.

For example, the thickness of the first electron transport sub-layer 1031 is greater than the thickness of the second electron transport sub-layer 1032 including the lithium metal, and the first electron transport sub-layer 1031 is closer to the light-emitting layer 102 compared to the second electron transport sub-layer 1032, which can minimize the damage to the light-emitting layer during the formation of the second electrode layer by the magnetron sputtering process, thereby ensuring electron injection and electron transport capability.

For example, in one example, as shown in FIG. 2, the material of the first electron transport sub-layer 1031 includes the first electron transport material, the material of the second electron transport sub-layer 1032 includes the lithium metal and the second electron transport material, and the thickness of the first electron transport sub-layer 1031 is 2 to 6times the thickness of the second electron transport sub-layer 1032. For example, the thickness of the first electron transport sub-layer 1031 is twice, three times, four times, five times, or six times the thickness of the second electron transport sub-layer 1032, and the embodiments of the present disclosure are not limited to this. For example, the thickness of the first electron transport sub-layer 1031 ranges from 600 angstroms to 1000 angstroms, the thickness of the second electron transport sub-layer 1032 ranges from 150 angstroms to 250 angstroms, and the thickness of the first electrode layer 104 ranges from 600 angstroms to 1000 angstroms. For example, the first electron transport material is the same as the second electron transport material, or the first electron transport material is different from the second electron transport material, and the conductivity of the first electron transport material is greater than the conductivity of the second electron transport material, or the material of the first electron transport sub-layer 1031 is the first electron transport material doped with the lithium metal, the first electron transport material is the same as the second electron transport material, but the mass percentage content of the lithium metal doped in the first electron transport material is lower than the mass percentage content of the lithium metal doped in the second electron transport material. For example, in one example, the mass percentage content of the lithium metal doped in the first electron transport material ranges from 1% to 5%, and the mass percentage content of the lithium metal doped in the second electron transport material ranges from 5% to 12%.

For example, in one example, as shown in FIG. 2, the thickness of the first electron transport sub-layer 1031 is 800 angstroms, the thickness of the second electron transport sub-layer 1032 is 200 angstroms, the thickness of the first electrode layer 104 is 800 angstroms, and in the second electron transport sub-layer 1032, the mass doping ratio of the lithium metal is 10%.

For example, in the above example, dividing the single-layer electron transport layer with a thickness of 800 angstroms to 1200 angstroms into a two-layer stacked structure can minimize the process damage of 17.0 and ensure the electron injection capability. At the same time, the optical cavity length of the entire organic electroluminescent device remains unchanged, and the decrease in lithium metal absorption will significantly improve the light-emitting efficiency of the organic electroluminescent device.

It should be noted that during the formation of the second electrode layer using the magnetron sputtering method, the thickness of damage to the organic layer is usually around 200 angstroms. The thickness of a conventional single-layer electron transport layer formed by the electron transport material doped with the lithium metal ranges from 800 angstroms to 1200 angstroms, and the material of the single-layer electron transport layer is a high concentration lithium metal doped electron transport material, although the high concentration lithium metal doped electron transport material can ensure the electron injection effect, the light-emitting efficiency of the formed organic electroluminescent device will be decreased due to the absorption of light by the lithium metal. If the single-layer electron transport layer is designed as a multilayer stacked electron transport layer, the concentration of the lithium metal doped in the multilayer stacked electron transport layer varies, or some layers are doped with the lithium metal, while others are not, this can ensure the performance of the organic electroluminescent device, and can also avoid the problem of reducing light-emitting efficiency of the organic electroluminescent device caused by the absorption of light by the lithium metal.

FIG. 3 is a schematic cross-sectional diagram of further another organic electroluminescent device provided by at least one embodiment of the present disclosure, as shown in FIG. 3, the organic eleetroluminescent device 100 further includes a hole blocking layer 105, a carrier generation layer 106, a hole transport layer 107, and a second electrode layer 108. The light-emitting layer 102 includes a first blue light-emitting layer 1021, a yellow light-emitting layer 1022, and a second blue light-emitting layer 1023 that are spaced apart. The carrier generation layer 106 is provided between the layers of the light-emitting layer 102, the carrier generation layer 106 includes a first carrier generation layer 1061 and a second carrier generation layer 1062 that are spaced apart from each other, in the direction from the first electrode layer 104 to the second electrode layer 108, each of the layers and the thicknesses of each of the layers are as follows: the thickness of the first electrode layer 104 ranges from 600 angstroms to 1000 angstroms, the thickness of the second electron transport sub-layer 1032 ranges from 150 angstroms to 250 angstroms, the thickness of the first electron transport sub-layer 1031 ranges from 600 angstroms to 1000 angstroms, the thickness of the hole barrier layer 105 ranges from 50 angstroms to 150 angstroms, the thickness of the first blue light-emitting layer 1021 ranges from 200 angstroms to 300 angstroms, the thickness of the first carrier generation layer 1061 ranges from 300 angstroms to 600 angstroms, the thickness of the yellow light-emitting layer 1022 ranges from 400 angstroms to 600 angstroms, the thickness of the second carrier generation layer 1062 ranges from 300 angstroms to 600 angstroms, the thickness of the second blue light-emitting layer 1023 ranges from 200 angstroms to 300 angstroms, the thickness of the hole transport layer 107 ranges from 400 angstroms to 600 angstroms, and the thickness of the second electrode layer 108 ranges from 700 angstroms to 1000 angstroms.

For example, the first blue light-emitting layer 1021, the yellow light-emitting layer 1022, and the second blue light-emitting layer 1023 can be respectively formed using the vapor deposition process. The hole blocking layer 105, the carrier generation layer 106, and the hole transport layer 107 can also be formed by using either the vapor deposition process or the inkjet printing process, respectively. The embodiments of the present disclosure are not limited to this.

For example, the process of forming the second electrode layer 108 includes depositing, coating, or sputtering a second electrode film on the base substrate 101, and then performing a single patterning process on the second electrode film to form the second electrode layer 108. The single patterning process includes coating photoresist, exposing and developing the photoresist to form a photoresist pattern, and using the photoresist pattern as a mask to etch the second electrode film to form the pattern of the second electrode layer, then peeling off the photoresist.

For example, in the above embodiment shown in FIG. 2 and FIG. 3, the first electron transport material and the second electron transport material are the same or different, the lowest unoccupied molecular orbital energy levels of the first electron transport material and the second electron transport material both range from −2.75 eV to −2.9 eV, and the highest occupied molecular orbital energy levels of the first electron transport material and the second electron transport material both range from −6.0 eV to −6.2 eV, and electron mobilities of the first electron transport material and the second electron transport material both range from 10⁻³ cm²/(V*s) to 10⁻² cm²/(V*s).

For example, in the embodiment shown in FIG. 2 and FIG. 3, arranging the electron transport layer 103 to include the first electron transport sub-layer 1031 and the second electron transport sub-layer 1032 that are stacked can prolong the light-emitting lifetime of the organic electroluminescent device 200 by 8.9%, and the color dots correspondingly change from (0.309, 0.3) to (0.311, 0.314). That is, while ensuring the light-emitting lifetime of the organic electroluminescent device 200, the light-emitting efficiency is improved.

FIG. 4 is a schematic cross-sectional diagram of further another organic electroluminescent device provided by at least one embodiment of the present disclosure. In another example, as shown in FIG. 4, the organic electroluminescent device 200 includes a light-emitting layer 202, a first electron transport sub-layer 2031, a second electron transport sub-layer 2032, and a first electrode layer 204 sequentially stacked on a base substrate 201. The material of the first electron transport sub-layer 2031 includes the first electron transport material, and the material of the second electron transport sub-layer 2032 includes the lithium metal and the second electron transport material. The thickness of the first electron transport sub-layer 2031 is 3 to 15 times the thickness of the second electron transport sub-layer 2032. For example, the thickness of the first electron transport sub-layer 2031 is 3 times, 4 times, 5 times, 6 times, 7 times, 8 times, 9 times, 10 times, 11 times, 12 times, 13 times, 14 times, or 15 times the thickness of the second electron transport sub-layer 2032, and the embodiments of the present disclosure are not limited to this. For example, the thickness of the first electron transport sub-layer 2031 ranges from 1000 angstroms to 1500 angstroms, the thickness of the second electron transport sub-layer 2032 ranges from 100 angstroms to 300 angstroms, and the thickness of the first electrode layer 204 ranges from 400 angstroms to 600 angstroms. For example, the first electron transport material is the same as the second electron transport material, or the first electron transport material is different from the second electron transport material, and the conductivity of the first electron transport material is greater than the conductivity of the second electron transport material, or the material of the first electron transport sub-layer 1031 is the first electron transport material doped with the lithium metal, and the first electron transport material is the same as the second electron transport material, however, the mass percentage content of the lithium metal doped in the first electron transport material is lower than the mass percentage content of the lithium metal doped in the second electron transport material. For example, in one example, the mass percentage content of the lithium metal doped in the first electron transport material ranges from 1% to 5%, and the mass percentage content of the lithium metal doped in the second electron transport material ranges from 5% to 12%.

For example, in another example, as shown in FIG. 4, the thickness of the first electrode layer 204 is reduced, and the total thickness of the first electron transport sub-layer 2031 and the second electron transport sub-layer 2032 is increased relative to the thickness of the single-layer electron transport layer.

For example, in another example, as shown in FIG. 4, the thickness of the first electron transport sub-layer 2031 is 1250 angstroms, the thickness of the second electron transport sub-layer 2032 is 200 angstroms, the thickness of the first electrode layer 204 is 300 angstroms, and in the second electron transport sub-layer 2032, the mass doping ratio of the lithium metal is 10%.

For example, in the embodiment shown in FIG. 4, the first electron transport material and the second electron transport material are the same or different, and the lowest unoccupied molecular orbital energy levels of the first electron transport material and the second electron transport material both range from −2.75 eV to −2.9 eV, and the highest occupied molecular orbital energy levels of the first electron transport material and the second electron transport material both range from −6.0 eV to −6.2 eV, and electron mobilities of the first electron transport material and the second electron transport material both range from 10⁻³ cm²/(V*s) to 10⁻² cm²/(V*s).

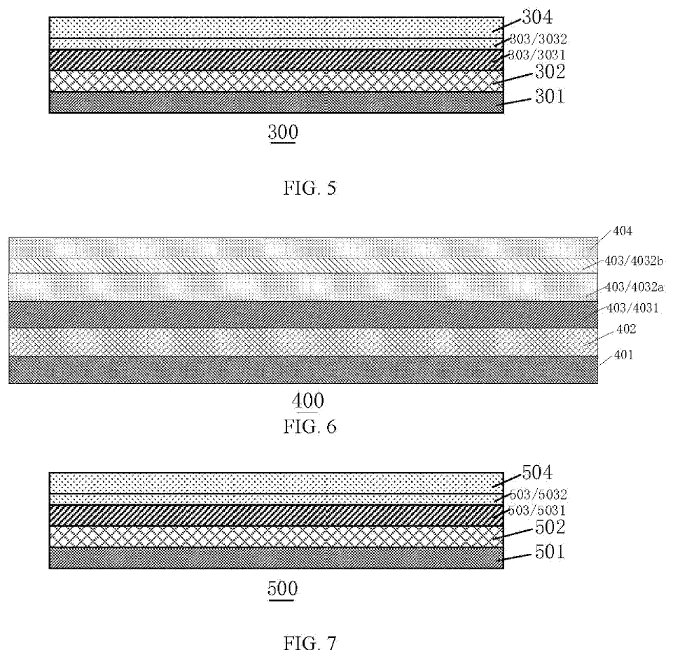

FIG. 5 is a schematic cross-sectional diagram of further another organic electroluminescent device provided by at least one embodiment of the present disclosure, as shown in FIG. 5, the organic eleetroluminescent device 300 includes a light-emitting layer 302, a first electron transport sub-layer 3031, a second electron transport sub-layer 3032, and a first electrode layer 304 sequentially stacked on a base substrate 301. The first electron transport sub-layer 3031 includes the first electron transport material, and the material of the second electron transport sub-layer 3032 includes the lithium metal. As shown in FIG. 5, the electron transport layer 303 includes a stacked two-layer structure. Of course, the number of the layers included in the electron transport layer 303 is not limited to this, and the electron transport layer 303 may also be a structure with more layers. The material of the second electron transport sub-layer 3032 may include other metals in addition to the lithium metal to form an alloy of the lithium and other metals, and the embodiments of the present disclosure are not limited to this.

For example, as shown in FIG. 5, in one example, the second electron transport sub-layer 3032 is formed by an alloy material of the lithium metal and yttrium metal. The alloy material formed by the lithium metal and the yttrium metal can resist the damage caused by the process of forming the first electrode layer 304 to the light-emitting layer 102, and can also achieve the effective electron injection. The first electron transport sub-layer 3031 can be formed only by the first electron transport material, and the electron mobility of the first electron transport material ranges from 10⁻² cm²/(V*s) to 10⁻¹ cm²/(V*s).

For example, as shown in FIG. 5, in one example, in the direction perpendicular to the main surface of the base substrate 301, the thickness of the second electron transport sub-layer 3032 ranges from 5 nm to 15 nm, and the thickness of the first electron transport sub-layer 3031 ranges from 70 nm to 90 nm. For example, the thickness of the second electron transport sub-layer 3032 is 5 nm, 6 nm, 7 nm, 8 nm, 9 nm, 10 nm, 11 nm, 12 nm, 13 nm, 14 nm or 15 nm, and the thickness of the first electron transport sub-layer 3031 is 70 nm, 75 nm, 80 nm, 85 nm or 90 nm, which is not limited by the embodiments of the present disclosure.

FIG. 6 is a schematic cross-sectional diagram of further another organic electroluminescent device provided by at least one embodiment of the present disclosure, as shown in FIG. 6, the organic electroluminescent device 400 includes a light-emitting layer 402, a first electron transport sub-layer 4031, a second electron transport sub-layer 4032, and a first electrode layer 404 sequentially stacked on a base substrate 401. The first electron transport sub-layer 4031 includes the first electron transport material, and the material of the second electron transport sub-layer 4032 includes the lithium metal. As shown in FIG. 6, the electron transport layer 403 includes a stacked three-layer structure. Of course, the number of the layers included in the electron transport layer 403 is not limited to this, and the electron transport layer 403 may also be a structure with more layers. The material of the second electron transport sub-layer 4032 may include other metals in addition to the lithium metal to form an alloy of the lithium metal and other metals, and the embodiments of the present disclosure are not limited to this.

For example, as shown in FIG. 6, the second electron transport sub-layer 4032 includes a first portion 4032a and a second portion 4032b that are stacked. The material of the first portion 4032a includes the second electron transport material, and the lithium metal is doped in the second electron transport material in the first portion 4032a. The second portion 4032b is formed by an alloy material of the lithium metal and yttrium metal, and the first electron transport sub-layer 4031 only includes the first electron transport material, and in the direction perpendicular to the main surface of the base substrate 401, the thickness of the first electron transport sub-layer 4031 is less than the thickness of the second electron transport sub-layer 4032, that is, the thickness of the first electron transport sub-layer 4031 is less than the sum of the thicknesses of the first portion 4032a and the second portion 4032b included in the second electron transport sub-layer 4032.

For example, as shown in FIG. 6, the electron mobilities of the first electron transport material and the second electron transport material both range from 10⁻³ cm²/(V*s) to 10⁻² cm²/(V*s), so as to better realize electron injection and transport.

For example, as shown in FIG. 6, in the direction perpendicular to the main surface of the base substrate 401, the thickness of the second portion 4032b ranges from 5 nm to 15 nm, and the sum of the thicknesses of the first electron transport sub-layer 4031 and the first portion 4032a ranges from 70 nm to 90 nm. The thickness of the second portion 4032b formed by the alloy material of the lithium metal and the yttrium metal is 0.05 to 0.2 times the sum of the thicknesses of the first electron transport sub-layer 4031 and the first portion 4032a. The embodiments of the present disclosure are not limited to this.

For example, in the second portion 4032b, the mass ratio of the lithium metal to the yttrium metal ranges from 5:4 to 6:1. For example, the mass ratio of the lithium metal to the yttrium metal is 2:1, 3:1, 4:1, 5:1, or 6:1, etc. The embodiments of the present disclosure are not limited to this.

FIG. 7 is a schematic cross-sectional diagram of further another organic electroluminescent device provided by at least one embodiment of the present disclosure. In another example, as shown in FIG. 7, the organic electroluminescent device 500 includes a light-emitting layer 502, an electron transport layer 503, and a first electrode layer 504 sequentially stacked on a base substrate 501. The electron transport layer 503 includes a first electron transport sub-layer 5031 and a second electron transport sub-layer 5032 that are stacked, and the first electron transport sub-layer 5031 is sandwiched between the light-emitting layer 502 and the second electron transport sub-layer 5032. The material of the first electron transport sub-layer 5031 includes a third electron transport material and the lithium metal doped in the third electron transport material. The second electron transport sub-layer 5032 is formed of an alloy material of magnesium metal and silver metal, the second electron transport sub-layer 5032 is located between the first electrode layer 504 and the first electron transport sub-layer 5031. The second electron transport sub-layer 5032 can affect the first electron transport sub-layer 5031 during the formation of the first electrode layer 504 by the magnetron sputtering method, thereby ensuring electron injection and transport, and prolonging the lifetime of the organic electroluminescent device while ensuring the light-emitting efficiency.

For example, in one example, as shown in FIG. 7, in the second electron transport sub-layer 5032, the mass ratio of the magnesium metal to the silver metal ranges from 9:1 to 8:2. For example, the mass ratio of the magnesium metal to the silver metal is 9:1, 8:1, or 8:2, etc., which is not limited by the embodiments of the present disclosure.

For example, in one example, in the direction perpendicular to the main surface of the base substrate 501, the thickness of the second electron transport sub-layer 5032 ranges from 2 nm to 5 nm, and the thickness of the first electron transport sub-layer 5031 ranges from 73 nm to 100 nm. For example, the thickness of the second electron transport sub-layer 5032 is 2 nm, 3 nm, 4 nm, or 5 nm, etc., and the thickness of the first electron transport sub-layer 5031 is 73 nm, 75 nm, 80 nm, 85 nm, 90 nm, 95 nm, or 100 nm, etc., which is not limited by the embodiments of the present disclosure.

For example, in another example, as shown in FIG. 7, the thickness of the first electrode layer 304 is reduced. In the direction perpendicular to the main surface of the base substrate 501, the thickness of the second electron transport sub-layer 5032 ranges from 2 nm to 5 nm, and the thickness of the first electron transport sub-layer 5031 ranges from 100 nm to 120 nm.

For example, in one example, as shown in FIG. 7, the light-emitting layer 502 includes a blue light-emitting layer 5021, a red light-emitting layer 5022, and a green light-emitting layer 5023 that are stacked, in the direction perpendicular to the main surface of the base substrate 501, the thickness of the blue light-emitting layer 5021 ranges from 200 angstroms to 300 angstroms. For example, the thickness of the blue light-emitting layer 5021 is 200 angstroms, 230 angstroms, 250 angstroms, 280 angstroms, or 300 angstroms. The thickness of the red light-emitting layer 5022 ranges from 100 angstroms to 200 angstroms, for example, the thickness of the red light-emitting layer 5022 is 100 angstroms, 120 angstroms, 140 angstroms, 160 angstroms, 180 angstroms, or 200 angstroms. The thickness of the green light-emitting layer 5023 ranges from 400 angstroms to 500 angstroms. For example, the thickness of the green light-emitting layer 5023 is 400 angstroms, 420 angstroms, 440 angstroms, 460 angstroms, 480 angstroms, or 500 angstroms.

FIG. 8 is a schematic cross-sectional diagram of further another organic electroluminescent device provided by at least one embodiment of the present disclosure, as shown in FIG. 8, the organic electroluminescent device 600 includes a light-emitting layer 602, an electron transport layer 603, and a first electrode layer 204 sequentially stacked on a base substrate 601. Although in FIG. 8, the electron transport layer 603 includes a first electron transport sub-layer 6031 and a second electron transport sub-layer 6032 that are stacked, the embodiments of the present disclosure are not limited to this. The materials and the thicknesses of the first electron transport sub-layer 6031 and the second electron transport sub-layer 6032 can be referred to the relevant descriptions in any one of the embodiments mentioned above, and the embodiments shown in FIG. 8 are not limited to this. For example, in the structure shown in FIG. 8, the organic electroluminescent device 600 further includes a second electrode layer 608 located on the side of the light-emitting layer 602 away from the first electrode layer 604.

For example, the second electrode layer 608 may adopt a metal material, for example, adopt any one or more of magnesium (Mg), silver (Ag), copper (Cu), aluminum (Al), titanium (Ti), or molybdenum (Mo), or an alloy material of the above metals, such as aluminum neodymium alloy (AlNd) or molybdenum niobium alloy (MoNb). The second electrode layer 608 may be a single-layer structure, a multilayer composite structure, such as Ti/Al/Ti, or a stacked structure formed by a metal and a transparent conductive material, such as ITO/Ag/ITO, Mo/AlNd/ITO and other reflective materials. However, the embodiments of the material of the second electrode layer 608 are not limited to this, as long as the material of the second electrode layer 608 is a metal material with high reflectivity.

For example, in the structure shown in FIG. 8, the organic electroluminescent device 600 further includes: a hole blocking layer 605, a carrier generation layer 606, and a hole transport layer 607.

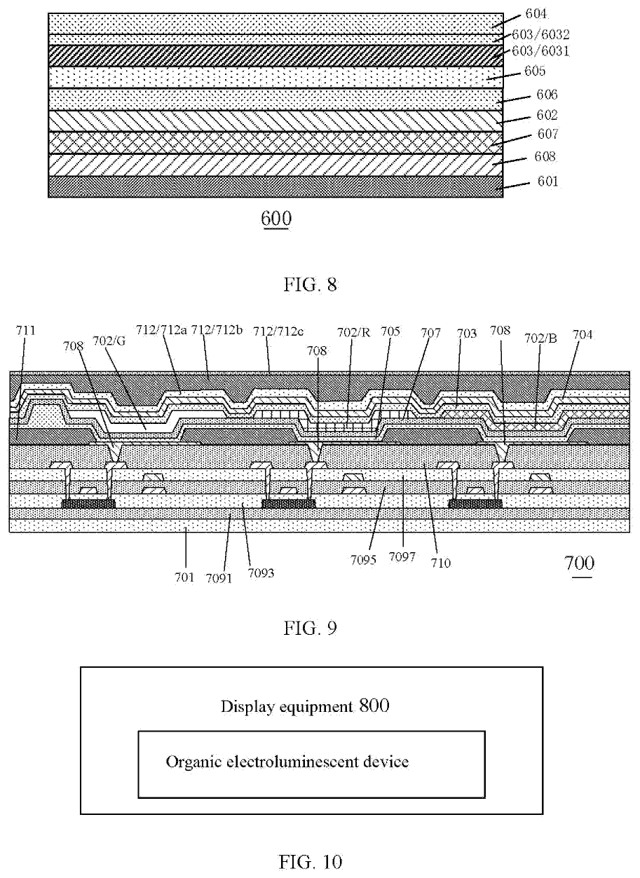

FIG. 9 is a schematic cross-sectional diagram of further another organic electroluminescent device provided by at least one embodiment of the present disclosure, as shown in FIG. 9, the organic electroluminescent device 700 further includes a pixel circuit structure provided on the base substrate 701. The pixel circuit structure includes a plurality of transistors and at least one storage capacitor. For example, the pixel circuit structure is designed as 2T1C, 3T1C, 5T1C, 7T1C, or 8T1C. FIG. 9 illustrates three sub-pixels as an example, and the pixel circuit structure of each sub-pixel is illustrated by using only one transistor and one storage capacitor as an example.

For example, in one example, the pixel circuit structure includes a first insulation layer 7091, an active layer pattern 7092, and a second insulation layer 7093 sequentially arranged on a base substrate 701, as well as a first gate metal layer pattern 7094 arranged on the second insulation layer 7093. The first gate metal layer pattern 7094 at least includes a first gate electrode and a first capacitor electrode. A third insulation layer 7095 and a second gate metal layer pattern 7096 are sequentially arranged on the first gate metal layer pattern 7094. The second gate metal layer pattern 7096 at least includes a second capacitor electrode, and the position of the second capacitor electrode corresponds to the position of the first capacitor electrode. A fourth insulation layer 7097 is arranged on the second gate metal layer pattern 7096, and at least two first via holes are provided on the fourth insulation layer 7097, the two first via holes sequentially penetrate the fourth insulation layer 7097, the third insulation layer 7095, and the second insulation layer 7093 to expose the surface of the active layer pattern 7092. A source and drain metal layer pattern 7098 is arranged on the fourth insulation layer 7097, the source and drain metal layer pattern 7098 at least includes a first source electrode and a first drain electrode located in the display region. The first source electrode and the first drain electrode can be respectively connected to the first active layer included in the active layer pattern 7092 through the first via holes.

In the pixel circuit structure of the display region, the first active layer, the first gate electrode, the first source electrode, and the first drain electrode can form a first transistor, and the first capacitor electrode and the second capacitor electrode can form a first storage capacitor.

For example, in some embodiments, the materials of the first insulation layer 7091, the second insulation layer 7093, the third insulation layer 7095, and the fourth insulation layer 7097 include any one or a combination of more of silicon oxide (SiOx), silicon nitride (SiNx), and silicon nitride (SiON). The first insulation layer 7091 to the fourth insulation layer 7097 may respectively have a single-layer structure, a multilayer structure, or a composite layer structure. The first insulation layer 7091 can act as a buffer layer to improve the water oxygen resistance of the base substrate 701; the second insulation layer 7093 and the third insulation layer 7095 can be gate insulation (GI) layers; the fourth insulation layer 7097 can be an interlayer insulation (ILD) layer. The materials of the first gate metal layer pattern 7094, the second gate metal layer pattern 7096, and the source and drain metal layer pattern 7098 can adopt a metal material, such as any one or more of silver (Ag), copper (Cu), aluminum (Al), titanium (Ti), and molybdenum (Mo), or an alloy material formed by multiple of the above metals, such as aluminum neodymium alloy (AlNd) or molybdenum niobium alloy (MoNb), and the first gate metal layer pattern 7094, the second gate metal layer pattern 7096 and the source and drain metal layer pattern 7098 can also respectively have a single-layer structure or a multilayer composite structure, such as Ti/Al/Ti. The material of the active layer pattern 7092 may include one or more materials such as amorphous indium gallium zinc oxide (a-IGZO), zine oxynitride (ZnON), indium zine tin oxide (IZTO), amorphous silicon (a-Si), polycrystalline silicon (p-Si), hexathiophene, polythiophene, and so on, that is, the embodiments of the present disclosure are applicable to transistors manufactured based on oxide technology, silicon technology, and organic matter technology.

For example, as shown in FIG. 9, the organic electroluminescent device further includes a planarization layer 710 arranged on the pixel circuit structure. The formation process of the planarization layer 710 includes coating an organic planarization film on the base substrate 701 formed with the pixel circuit structure, so as to cover the main surface of the entire base substrate 701, and using mask, exposure, and development processes to form a plurality of second via holes in the organic planarization film in the display region. The organic planarization film inside the plurality of second via holes are developed to expose the surface of the first drain electrode of the first transistor of the pixel driving circuit corresponding to the sub-pixels of different colors.

For example, as shown in FIG. 9, the second electrode layer 708 is arranged on a side of the planarization layer 710 away from the base substrate 701. The process of forming the second electrode layer 708 includes depositing a conductive film on the base substrate 701 formed with the above pixel circuit structure and the planarization layer 710, and patterning the conductive film through a patterning process to form the second electrode layer 708. The second electrode corresponding to the red sub-pixel R is connected to the first drain electrode of the first transistor through a second via hole, the second electrode corresponding to the green sub-pixel G is connected to the first drain electrode of the first transistor of the green sub-pixel through a second via hole, and the second electrode corresponding to the blue sub-pixel B is connected to the first drain electrode of the first transistor of the blue sub-pixel through a second via hole. For example, the material and specific formation process of the second electrode layer 708 can be referred to the relevant descriptions mentioned above, which will not be repeated herein.

For example, in the structure shown in FIG. 9, the organic electroluminescent device further includes a pixel definition layer 711 arranged on the second electrode layer 708, the pixel definition layer 711 includes a plurality of openings and pixel definition portions that separate the plurality of openings. The plurality of openings in the pixel definition layer 711 can divide the base substrate 701 into a plurality of sub-pixel regions arranged in an array, each of the sub-pixel regions corresponds to at least one thin film transistor, and each of the openings is provided with a light-emitting layer 702, and the pixel definition portions included in the pixel definition layer 711 separate the light-emitting layers 702 in the openings. A hole blocking layer 705, a carrier generation layers 706, and a hole transport layers 707 that are stacked are also arranged in the plurality of openings respectively included in the pixel definition layer 711.

For example, as shown in FIG. 9, the material of the pixel definition layer 711 includes an organic material, such as at least one of polyimide, fluorinated polyimide, fluorinated polymethyl methacrylate, and polysiloxane.

For example, the process of forming the pixel definition layer 711 can be as follows: forming a pixel definition layer film on the second electrode layer 708 by depositing, coating, or sputtering, and performing a single patterning process on the pixel definition layer film to form the pixel definition layer. The single patterning process can include coating photoresist, exposing and developing the photoresist to form a photoresist pattern, using the photoresist pattern as a mask to etch the pixel definition layer film to form a pattern of the pixel definition layer, and then peeling off the photoresist.

For example, in the structure shown in FIG. 9, the organic electroluminescent device 700 further includes a hole blocking layer 705, a hole transport layer 707, and a first electrode layer 704 arranged in each of the openings and above the pixel definition portions. The hole blocking layer 705, the hole transport layer 707, and the first electrode layer 704 are all common connection layers of the plurality of sub-pixels. The materials of the hole blocking layer 705, the carrier generation layer 706, the hole transport layer 707, and the first electrode layer 704 can refer to conventional structures and material selections, and the embodiments of the present disclosure are not limited to this. It should be noted that, in FIG. 9, although the electron transport layer 703 is shown in a single-layer form, the electron transport layer 703 may include a multilayer structure.

For example, as shown in FIG. 9, the organic electroluminescent device further includes an encapsulation layer 712 arranged on the base substrate 701, the encapsulation layer 712 may include a first encapsulation layer 712a. a second encapsulation layer 712b, and a third encapsulation layer 712e that are stacked. The first encapsulation layer 712a adopts an inorganic material and covers the first electrode layer 704 in the display region. The second encapsulation layer 712b adopts an organic material. The third encapsulation layer 712e adopts an inorganic material and covers the first encapsulation layer 712a and the second encapsulation layer 712b. However, the embodiments are not limited to this. In some examples, the encapsulation layer may adopt a five-layer structure including an inorganic layer, an organic layer, an inorganic layer, an organic layer, and an inorganic layer that are stacked sequentially.

For example, FIG. 10 is a block diagram of a display equipment provided by at least one embodiment of the present disclosure, as shown in FIG. 10, the display equipment 800 includes the organic electroluminescent device in any one of the above embodiments. The display equipment 800 can be any product or component with a display function, such as an electronic paper, a mobile phone, a tablet, a television, a monitor, a laptop, a digital photo frame, a navigation device, and so on. The display equipment includes a small and medium sized electronic equipment such as a tablet computer, a smartphone, a head mounted display, a car navigation unit, a camera, a central information display (CIDs) provided in vehicles, a watch type electronic device or other wearable devices, a personal digital assistant (PDA), a portable multimedia player (PMP), a game console, as well as a medium and large sized electronic equipment such as a television, an external billboard, a monitor, a household appliance containing a display screen, a personal computer and a laptop. The electronic equipment described above can represent a simple example for applying the display equipment, and those skilled in the art may recognize that the display equipment can also be applied to any other electronic equipments with a display function without departing from the spirit and scope of the present disclosure.

The following statements should be noted:
(1) The drawings involve only the structure(s) in connection with the embodiment(s) of the present disclosure, and other structure(s) can be referred to common design(s).
(2) For clarity, in the drawings used to describe the embodiments of the present disclosure, the thicknesses of layers or regions are enlarged or reduced, that is, the drawings are not drawn to actual scale.
(3) In case of no conflict, features in one embodiment or in different embodiments can be combined to obtain new embodiments.

What have been described above are only specific implementations of the present disclosure, the protection scope of the present disclosure is not limited thereto, and the protection scope of the present disclosure should be based on the protection scope of the claims.

1. An organic electroluminescent device, comprising:
a base substrate, and
a light-emitting layer, an electron transport layer, and a first electrode layer sequentially stacked on the base substrate,
wherein the electron transport layer comprises a multilayer structure that is stacked, and a material of at least one layer in the multilayer structure comprises lithium metal.

2. The organic electroluminescent device according to claim 1, wherein the electron transport layer comprises a first electron transport sub-layer and a second electron transport sub-layer that are stacked,
the first electron transport sub-layer is sandwiched between the light-emitting layer and the second electron transport sub-layer, and a material of the first electron transport sub-layer comprises a first electron transport material, and a material of the second electron transport sub-layer comprises the lithium metal.

3. The organic electroluminescent device according to claim 2, wherein the material of the second electron transport sub-layer further comprises a second electron transport material, the lithium metal is doped in the second electron transport material, and
in a direction perpendicular to a main surface of the base substrate, a thickness of the first electron transport sub-layer is greater than a thickness of the second electron transport sub-layer.

4. The organic electroluminescent device according to claim 3, wherein the thickness of the first electron transport sub-layer is 2 to 6 times the thickness of the second electron transport sub-layer.

5. The organic electroluminescent device according to claim 4, wherein the thickness of the first electron transport sub-layer ranges from 600 angstroms to 1000 angstroms, the thickness of the second electron transport sub-layer ranges from 150 angstroms to 250 angstroms, a thickness of the first electrode layer ranges from 600 angstroms to 1000 angstroms, and in the second electron transport sub-layer, a mass doping ratio of the lithium metal ranges from 5% to 12%.

6. The organic electroluminescent device according to claim 5, wherein the thickness of the first electron transport sub-layer is 800 angstroms, the thickness of the second electron transport sub-layer is 200 angstroms, and in the second electron transport sub-layer, the mass doping ratio of the lithium metal is 10%.

7. The organic electroluminescent device according to claim 3, wherein the thickness of the first electron transport sub-layer is 3 to 15 times the thickness of the second electron transport sub-layer.

8. The organic electroluminescent device according to claim 7, wherein the thickness of the first electron transport sub-layer ranges from 1000 angstroms to 1500 angstroms, the thickness of the second electron transport sub-layer ranges from 100 angstroms to 300 angstroms, and a thickness of the first electrode layer ranges from 400 angstroms to 600 angstroms.

9. The organic electroluminescent device according to claim 8, wherein the thickness of the first electron transport sub-layer is 1250 angstroms, the thickness of the second electron transport sub-layer is 200 angstroms, and the thickness of the first electrode layer is 300 angstroms.

10. The organic electroluminescent device according to claim 3, wherein lowest unoccupied molecular orbital energy levels of the first electron transport sub-layer and the second electron transport sub-layer both range from −2.75 eV to −2.9 eV,
highest occupied molecular orbital energy levels of the first electron transport sub-layer and the second electron transport sub-layer both range from −6.0 eV to −6.2 eV, and
electron mobilities of the first electron transport sub-layer and the second electron transport sub-layer both range from 10⁻³ cm²/(V*s) to 10⁻² cm²/(V*s).

11. The organic electroluminescent device according to claim 2, wherein the second electron transport sub-layer is formed of an alloy material of the lithium metal and yttrium metal.

12. The organic electroluminescent device according to claim 11, wherein an electron mobility of the first electron transport material ranges from 10⁻² cm²/(V*s) to 10⁻¹ cm²/(V*s).

13. The organic electroluminescent device according to claim 12, wherein in a direction perpendicular to a main surface of the base substrate, the thickness of the second electron transport sub-layer ranges from 5 nm to 15 nm, and the thickness of the first electron transport sub-layer ranges from 70 nm to 90 nm.

14. The organic electroluminescent device according to claim 2, wherein the second electron transport sub-layer comprises a first portion and a second portion that are stacked, a material of the first portion comprises a second electron transport material, and the lithium metal is doped in the second electron transport material; the second portion is formed of an alloy material of the lithium metal and yttrium metal, and in a direction perpendicular to a main surface of the base substrate, the thickness of the first electron transport sub-layer is smaller the thickness of the second electron transport sub-layer.

15. The organic electroluminescent device according to claim 14, wherein electron mobilities of the first electron transport material and the second electron transport material both range from 10⁻³ cm²/(V*s) to 10⁻² cm²/(V*s).

16. The organic electroluminescent device according to claim 15, wherein in the direction perpendicular to the main surface of the base substrate, the thickness of the second portion ranges from 5 nm to 15 nm, and a sum of thicknesses of the first electron transport sub-layer and the first portion ranges from 70 nm to 90 nm.

17. The organic electroluminescent device according to claim 1, wherein the electron transport layer comprises a first electron transport sub-layer and a second electron transport sub-layer that are stacked,
the first electron transport sub-layer is sandwiched between the light-emitting layer and the second electron transport sub-layer, and a material of the first electron transport sub-layer comprises a third electron transport material and the lithium metal doped in the third electron transport material, the second electron transport sub-layer is formed of an alloy material of magnesium metal and silver metal.

18. The organic electroluminescent device according to claim 17, wherein in the second electron transport sub-layer, a mass ratio of the magnesium metal to the silver metal ranges from 9:1 to 8:2.

19.-22. (canceled)

23. The organic electroluminescent device according to claim 1, further comprising:
a second electrode layer on a side of the light-emitting layer away from the first electrode layer,
wherein a material of the second electrode layer comprises at least one of aluminum, silver, molybdenum, and copper.

24. A display equipment, comprising the organic electroluminescent device according to claim 1.
